(19) United States
(12) Patent Application Publication
(10) Pub. No.: US 2010/0117624 A1
(43) Pub. Date: May 13, 2010

(54) NETWORK-DISTRIBUTED OSCILLOSCOPE AND METHOD OF OPERATION THEREOF

(75) Inventors: Martin D. Carroll, Watchung, NJ (US); Ilija Hadzic, Millington, NJ (US)

Correspondence Address: HITT GAINES, PC;ALCATEL-LUCENT, PO BOX 832570, RICHARDSON, TX, 75083, US

(73) Assignee: Alcatel-Lucent USA Inc., Murray Hill, NJ (US)

(21) Appl. No.: 12/268,711

(22) Filed: Nov. 11, 2008

(51) Int. Cl. G01R 13/20; G01R 23/16

(52) U.S. Cl. 324/76.25; 324/113

(57) ABSTRACT

A system and method for achieving oscilloscope functionality over a network. In one embodiment, the system includes: (1) a core having a local memory and configured to gather samples of an external signal based on a schedule at a specified sampling rate, write the samples into the local memory and transmit the samples over the network, and (2) a viewer couplable to the core over a network and configured to receive the samples over the network and display a waveform based on the samples.

### TECHNICAL FIELD OF THE INVENTION

The invention is directed, in general, to an oscilloscope and spectrum analyzer and a method of using the same.

### BACKGROUND OF THE INVENTION

The newest high-speed test instruments, such as oscilloscopes, including sampling oscilloscopes and those test instruments that can function as spectrum analyzers, are expensive, perhaps costing tens of thousands of dollars and heavy, perhaps weighing several tens of pounds. Therefore, there is a need in the art for a system and method to reduce the expense and weight of these instruments.

### SUMMARY OF THE INVENTION

One aspect of the invention provides a system. One embodiment of the system includes: (1) a core having a local memory and configured to gather samples of an external signal at a specified sampling rate, write the samples into the local memory based on a schedule and transmit the samples over the network, and (2) a viewer couplable to the core over a network and configured to receive the samples over the network and display a waveform based on the samples.

Another aspect of the invention provides a method, including: (1) receiving a schedule at an oscilloscope core, (2) storing samples of a received signal according to the schedule, and (3) transmitting, over a network, the stored samples.

In still yet another aspect, the invention further provides a method of: (1) selecting an oscilloscope type, (2) selecting a store specification, a transmit specification, or both (3) conveying a schedule including the store specification, the transmit specification, or both to an oscilloscope core over a network from a client machine, (4) receiving sampled waveforms over the network from the oscilloscope core, the sampled waveforms based upon the schedule, and (5) displaying the sampled waveforms on the viewer of the client machine.

### BRIEF DESCRIPTION OF THE DRAWINGS

For a more complete understanding of the invention, reference is now made to the following descriptions taken in conjunction with the accompanying drawings, in which:

FIG. 1 is a block diagram of one embodiment of a system for viewing waveforms that uses an oscilloscope core constructed according to the principles of the invention;

FIG. 2 is a block diagram of one embodiment of a logical organization of data structures stored in a local memory constructed according to the principles of the invention;

FIG. 3A illustrates an exemplary capture window having a plurality of display windows for use with an oscilloscope core constructed according to the principles of the invention;

FIG. 3B illustrates an example of a series of capture windows for performing a fast Fourier transform for use with a spectral analysis carried out by an oscilloscope core constructed according to the principles of the invention;

FIG. 4 illustrates an example of a capture window for sampling a periodic or pseudorandom waveform for use with an oscilloscope core constructed according to the principles of the invention;

FIG. 5A is a flow diagram of one embodiment of a method of displaying a waveform in real-time or otherwise carried out according to the principles of the invention; and

FIG. 5B is a flow diagram of one embodiment of a method of capturing a waveform in a window in real-time or otherwise carried out according to the principles of the invention.

### DETAILED DESCRIPTION

Generally, the present disclosure recognizes that conventional oscilloscopes and related conventional test instruments typically do not use or couple off-the-shelf personal computers (“PCs”). Instead, these conventional test instruments couple hardware that is substantially similar to hardware used in off-the-shelf PCs (e.g., mother board, hard disk, network card, video card, keyboard and mouse controller, etc.) and in a same physical enclosure with data acquisition hardware.

However, despite conventional oscilloscopes and related test instruments containing off-the-shelf PC hardware, conventional test instruments, nonetheless, do not behave like a general-purpose PC, but as a specialized piece of hardware. The present disclosure, therefore, recognizes an advantageous decoupling of the PC-like aspects of test instruments from data-acquisition aspects of test instruments. The present disclosure furthermore recognizes employing a network between the PC-like aspects of test instruments and the data-acquisition aspects of test instruments.

Conventional test instruments may connect a data acquisition box locally to a conventional viewer. These conventional test instruments may be able to utilize a bandwidth of a local bus, which can in some circumstances be greater than the bandwidth available in a typical network. However, conventional test instruments are not typically able to view waveforms at increased resolution and frequency and amplitude selectivity over a network.

Furthermore, while the conventional data collection hardware of test instruments may capture raw data in real-time, conventional data collection hardware typically must “down-sample” the raw data before providing it for analysis. This down-sampling can lead to various problems, such as information loss.

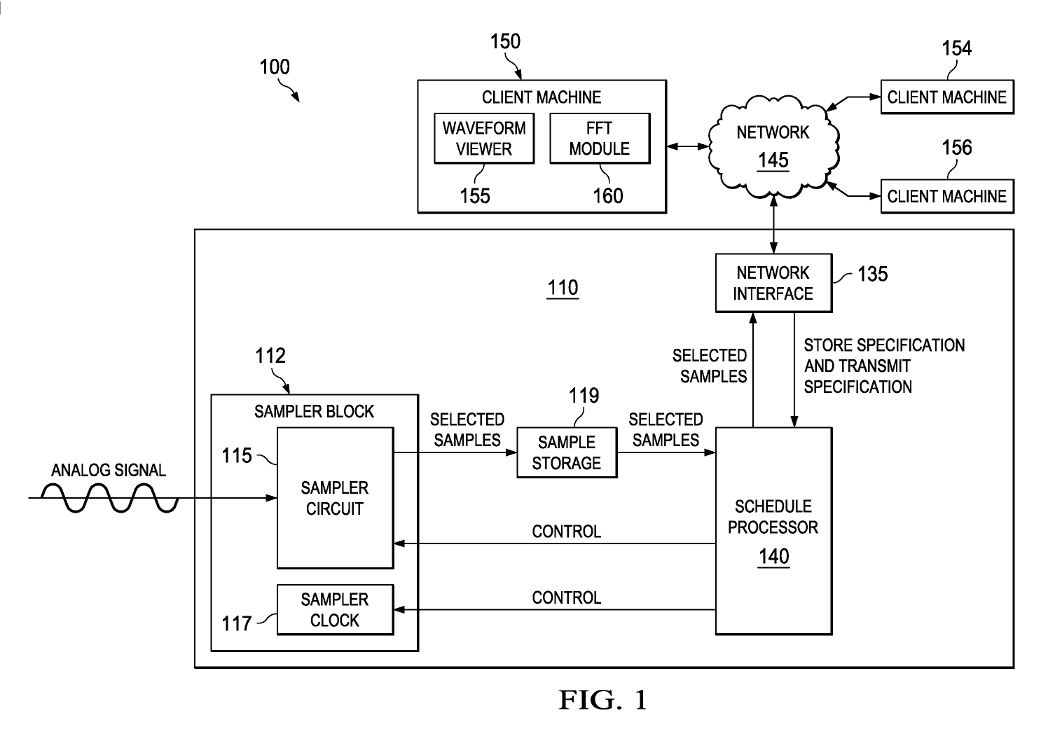

Turning now to FIG. 1, illustrated is a system 100, which can function variously as a network-distributed real-time scope, a network-distributed spectrum analyzer, and a network-distributed sampling scope. However, unlike the aforementioned conventional test instruments, the illustrated embodiment of an oscilloscope core 110 does not down-sample data. Instead, generally, a subset of raw external data is selectively stored as determined by store and transmit specifications and other information contained in schedules received in the core 110.

The store specification comprises zero or more store sample windows. Similarly, the transmit specification comprises zero or more transmit sample windows. A store sample window specifies which samples are to be stored locally on the core 110 for possible later retrieval by the client, via specific requests by a client. The transmit sample window specifies which samples are to be transmitted to the user as soon as they are gathered. At least a subset of the sampled data is conveyed according to the transmit specification across a network to a client machine 150. The client machine 150 includes a waveform viewer 155, typically software.

The core 110 can therefore adapt to the increased data transmission bandwidth capabilities of networks, and can advantageously employ increased network bandwidth to enable more precise real-time oscilloscope waveform viewing, and increased frequency and amplitude sensitivity, than generally available in the prior art. This can occur through such actions as increasing the size defined or the frequency of storage of data samples as determined by store specifications and transmission specifications of schedules.

Furthermore, the present disclosure recognizes significant advantages in performing data acquisition work in an oscilloscope core 110 as a separate unit from a waveform viewer 155, which is part of the client machine 150. The present disclosure recognizes advantages of configuring differing logical test instruments to reuse the same physical hardware, and to decouple the PC-like aspects of the hardware from the non PC-like aspects of the hardware. These significant advantages can include allowing much, perhaps even the totality, of the client machine 150 to be constructed from off-the-shelf PCs or PC components. This can lead to significant cost savings.

The core 110 is embodied as a separate unit that can be accessed over the network 145. The core 110 can be accessible from any machine on the network 145, such as the client machines 150, 154, and 156 that run appropriate software. Several employments of the core 110 and the client machine 150 will be described, with specific reference to the client machine 150. In some embodiments, the client machines 150, 154, 156 can act as, or otherwise emulate, a spectrum analyzer.

The present disclosure further recognizes that portability advantages accrue with employment of the core 110 as separate from the waveform viewer 155, as well. For example, the core 110 can be conveyed, perhaps wheeled, from room to room, to be coupled first to some circuits under test, perhaps to another, assuming a link to a network, such as a network 145, to be viewed by the client machines 156 or 157, thereby allowing for less weight or bulk to be transferred, as the client machines 150, 154, 156 can be stationary, thereby achieving a small, light, and relatively inexpensive core 110.

The present disclosure still further recognizes that, when compared to virtual instruments, such as National Instruments Lab-View®, such virtual instruments can use a similar network as used by the core 110, and could have similar available bandwidth. However, the core 110, as shall be explained below, due to an employment of received schedules for data capture, including transmit specifications for data transfer, can significantly reduce the amount of sample data that must be transferred over the network 145, as compared with a conventional virtual instrument. This decrease of sample data, therefore, allows for an increase of practicality of use of the oscilloscope core 110, and therefore, viewing options of the waveform viewer 155, as shall be explained below.

Generally, in the system 100, there is one schedule in use at a given time. The schedule can contain a trigger specification, a store specification, and a transmit specification. The transmit sample windows specify which samples are to be transmitted to the client as soon as they are gathered. Samples that fall within the store sample windows are also stored locally in the core 110 until such time as those samples are packetized and transmitted to the client per a client's explicit request.

The sample windows in the store specification can perfectly overlap, partially overlap, or be entirely disjoint from the sample windows in the transmit specification. Both a store and transmit sample window occurs after a temporal offset from the occurrence of a trigger, the trigger defined in a trigger specification. The sample windows also have a duration of storage of samples of the received signal. The length of the duration can also be defined in the schedule.

In the system 100, the core 110 is a specialized piece of hardware. The core 110 performs data capture, and in some embodiments, additional analysis work, on a received analog signal at a specified sampling rate. The coupled client machine 150 typically includes an off-the shelf PC with some additional viewer software, the waveform viewer 155.

The core 110 contains a sampler block 112. The sampler block 112 contains a sampler circuit 115 and a sampler clock 117. The sampler clock 117 is employed to time a sample of analog external signals and to control the sampler circuit 115. The sampler circuit 115 samples analog signals that it is ordered to do so as determined by a received schedule at a specified sampling rate. Then, the selected samples are conveyed to a sample storage memory 119 in a store sample window or transmit sample window, as appropriate, although the transmit sample window will then be immediately conveyed to the waveform viewer 155. As will be detailed below, in some embodiments, the core 110 can operate as at least one of two types of oscilloscope: a “real-time” emulated oscilloscope display type and a “periodic” oscilloscope emulated display type.

Coupled to the sampling block 110 and the sample storage 119 is a schedule processor 140. Generally, in the core 110, it is the schedule processor 140 that enables the core 110 to run at a high sampling speed as determined by the received store specifications and transmit specifications, as will be described below. The processor 140 processes the store and transmit specifications that are received from the client machine 150 via the network 145 by a network interface 135.

A coupled waveform viewer 155 controls the core 110 by providing it the schedule, including the store specification and the transmit specification over the network 145. Generally, the schedule informs the schedule processor 140 what data is to be sampled, and how it is to be transmitted. In one embodiment, the schedule includes an indication of a fixed or non-fixed sampling mode. The schedule can also include a trigger specification including: a signal identifier, a rising edge, falling edge and voltage level for triggering a storage of a subset of the waveform into a storage sample window or a transmission sample window. A signal identifier can be generally defined as an identifier to be used by the viewer 155 when displaying the sampled waveform.

The voltage can be determined by the sampler circuit 115 independently of the sampler clock 117. In some embodiments, the sample windows can be overlapping. Please note that the store specification and the transmit specification can be used independently of one another.

A schedule includes such information pertaining to, and including, a positive or negative offset time expressed relative to an occurrence of the trigger event and a duration of the time of the sampling regarding a storage of samples into a given store sample window or transmit sample window. The schedule processor 140 controls signal sampling behavior of the sampler clock 117 and the sampler block 112 based upon these schedules. The sampler block 112 then stores these sampled signals, based upon the schedules, into store windows. In some embodiments, the sampling rate is specified only once per schedule.

In one embodiment, the core 110 allows a relatively slow sampling rate of less than one giga-sample per second. In an alternative embodiment, the core 110 allows a relatively fast sampling rate of more than one gigahertz sampling frequency that can be remotely viewed by client machines 152, 152, 154. However, previous networked solutions only typically allowed several thousand hertz to be captured before down-sampling was required.

However, unlike the aforementioned conventional networked oscilloscopes and other test instruments, the illustrated embodiment of the core 110 does not down-sample data. Instead, generally, raw data is stored in the core 110 and then selectively conveyed across the network 145 to the client machine 150 as determined by various store specifications and transmit specifications of schedules. Otherwise, non-selected raw data is generally discarded and over-written with new data. The system 100, however, advantageously employs selected windows of non-down sampled data to be displayed by the waveform viewer 150.

As discussed above, based on contents of these received schedules, the processor 140 drives control signals to the sampler block 112. These control signals enable the schedule processor 140 to dynamically change the rate and phase shift of the sampler clock 117, and to dynamically instruct the sampler circuit 115 to start and stop writing samples into a local memory, such as the sample storage 119, at a specified location, as determined by these schedules, and the timing between samples. The schedule processor 140 also reads appropriate samples from sample storage 119 and transmits them to the remote viewer, as commanded by the transmit specifications.

In the system 100, these various elements of the core 110 can be logical blocks, and therefore, can be configured as differing forms of hardware, firmware, and software components. In one embodiment, the sampler clock 117 is implemented in hardware. The sampler circuit 115 is implemented in hardware using a combination of analog and digital components. The schedule processor 140 is implemented in a combination of hardware, firmware, and software. The hardware portion of the schedule processor 140 includes at least one of a special-purpose Application Specific Integrated Circuit (“ASIC”), a Field Programmable Gate Array (“FPGA”), or an embedded processor. If an FPGA is present, each embedded processor either is internal to an FPGA or is a self-contained external device. The firmware portion of the schedule processor 140 includes Hardware Description Language (“HDL”) code running on the FPGA or FPGAs. A software portion of the schedule processor 140 includes software code running on an embedded processor.

The coupled client machine 150 includes the waveform viewer 155. As will be described in more detail below, the waveform viewer 155 can be used to: a) process data from the core 110; b) display data from the core 110; and c) control the core 110.

In some further embodiments, the client machine 150 includes a software module that employs various signal processing techniques, such as a Fast Fourier Transform (“FFT”) using the FFT module 160. The FFT module 160 can be used to analyze a spectral content of the received data, although other forms of signal processing modules can also be used. Those of skill in the art should understand that an unbounded number of post-acquisition data processing can occur on the viewer, and an FFT is only an illustrative example.

Generally, a networked OC 110 should be less expensive than traditional oscilloscopes, as there is less hardware to buy, as generally in the oscilloscope system 100 there is not a need for a dedicated PC for the OC 110; instead, an off-the-shelf PC, perhaps having additional installed viewer software can be used. In at least some embodiments, OC 110 is more convenient to use than prior art oscilloscopes. With use of the OC 100, equipment that is moved from room to room when testing is smaller and lighter, and hence more portable, because the OC 110 does not contain components that normally exist in every PC. Instead, these parts are in the client machines 150, 154, and 156. Because off-the-shelf PCs (perhaps several of them) are likely to be available in a number of separate rooms and connected to the network 145 as client machines 150, 154, 156, they can be used to access the OC 100.

In alternative embodiments, a user of the core 110 could lease a software feature for a short period of time, and thus, effectively use the OC 110 as multiple test instruments. For example, an engineer who typically uses a real-time oscilloscope could “lease” a spectrum analyzer for one week, for example, by leasing the appropriate software. This new business model, while displacing the traditional business model in this market, could increase the market for scopes and allow new sources of revenue.

In some embodiments, the OC 110 uses published Application Programming Interface (“API”) software. In some further embodiments, “open source” software is employed and installed in the waveform viewer 155. Although none, some, or all of the software and firmware used in the system 100 can be open source, open source code is not required in the system 100.

New software, such as “open source” or published API software, could also allow and/or enable a new use of test equipment. In other words, the user can change the behavior (or “personality”) of the system 100 by installing new software or firmware. Such “personality-altering” software and firmware can be loaded either to the waveform viewer 155, the core 110, or both.

As an example of the former, in the system 100, by loading the FFT module 160 (and other related software) into the viewer 155, the user can change the personality of the system 100 into a spectrum analyzer. As an example of the latter, by installing the appropriate software and firmware into the core 110, the user can implement a modification of, or enhancement to, the semantics of how schedules are specified and processed. However, those of skill in the art should understand that an unbounded number of post-acquisition data processing can occur on the viewer, and an FFT is only an illustrative example.

It is noted that the ability to load personality-altering software and firmware into the viewer 155 and the core 110 is logically separate from the ability, found in modern devices (test equipment and otherwise), to install new versions of the base set of software and firmware. In the system 100, users can both upgrade base software and firmware, and load personality-altering software and firmware, in parallel. It should also be noted that the ability to load new firmware into the core is made possible by the presence of an FPGA in the core.

In one embodiment, the OC 110 is configured to present multiple logically independent virtual cores. This permits multiple viewers independently to gain access to and control the logically independent virtual cores. A networked oscilloscope infrastructure may then result with plural waveform viewers and virtual cores.

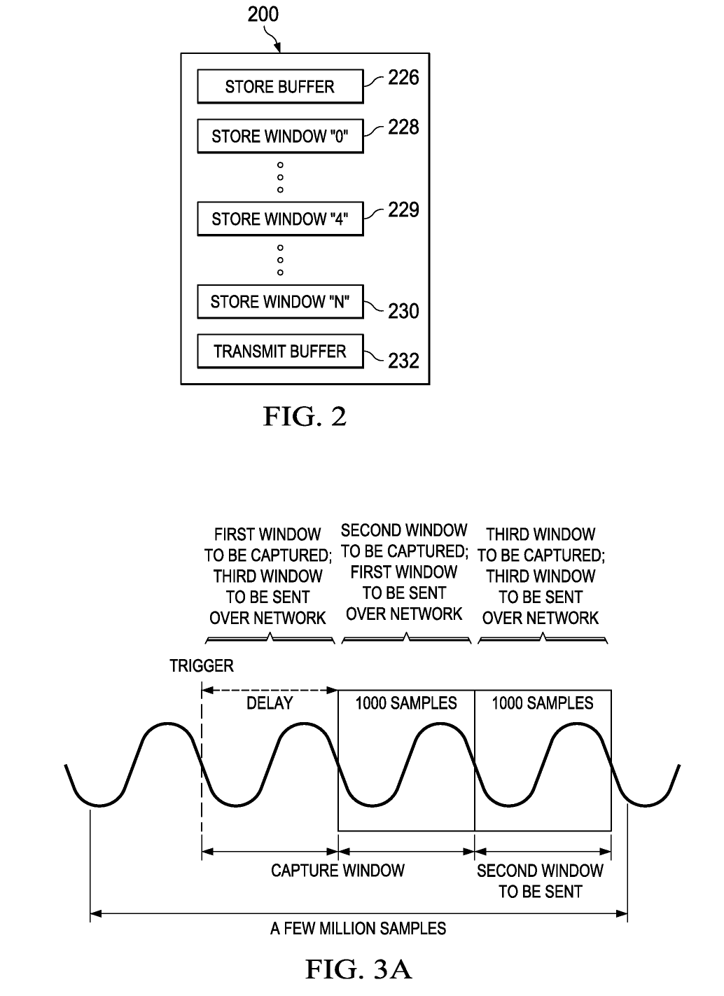

Turning briefly to FIG. 2, illustrated is a local memory storage 200, illustrated as having a plurality of logical subdivisions. The memory 200 is implemented in hardware, such as found in the sample storage 119. In at least some embodiments, the memory 200 is included in the sample storage 119. Analog signals are sampled and stored in at least three different logical regions of memory, as shown in FIG. 2.

Samples that are gathered by the sampler circuit 115 for potential insertion into a sampled store window, defined by a schedule, are temporarily stored in a store buffer 226. Samples that are stored per a store specification of a schedule are stored in zero or more store windows 228-230. Finally, samples being gathered for potential transmission per the transmit specifications are temporarily stored in a transmit buffer 232.

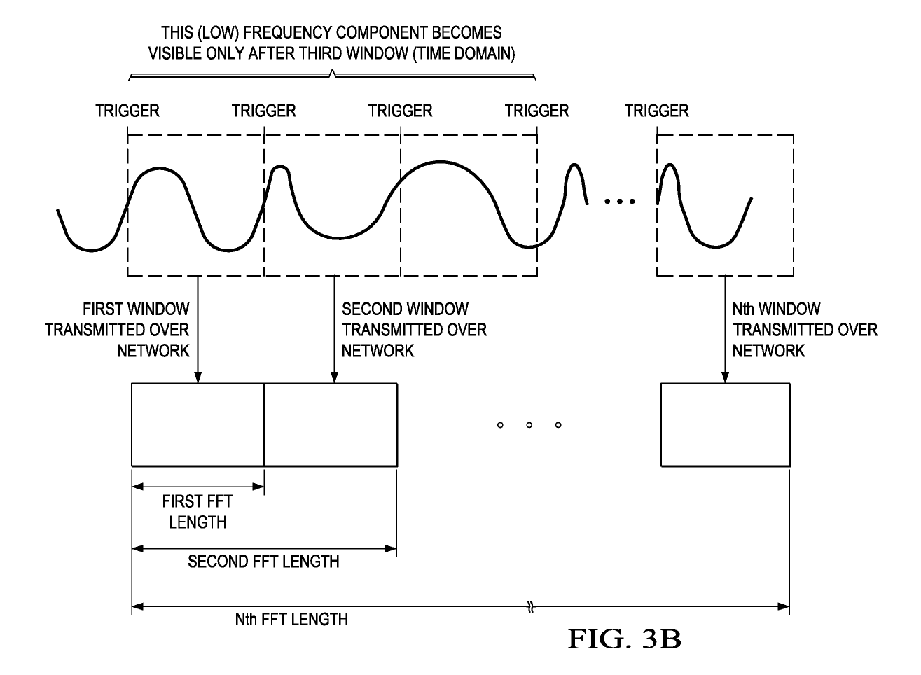

Turning back to FIG. 1, one specific employment of the oscilloscope core 110 will now be described. FIG. 1 will be described in conjunction of FIGS. 3A and 3B. Generally, regarding FIGS. 3A and 3B, the oscilloscope core 110 can be employed as an embodiment for sampling and displaying real-time waveform, i.e., it is in “real-time” sampling type.

A waveform is received at the sampler circuit 115 and stored in the store buffer 226. The sampler circuit 115 can include a digital-to-analog converter. The sampler clock 117 generates a clock signal, which is used by the sampler circuit 115. The sampler circuit 115 samples the external signal and stores the samples into sample storage. The sampled windows are defined by the schedules received from the client machine 150. As discussed above, the memory 200 includes various physical or logical locations for storage of a waveform comprising a series of given window samples. Exemplary characteristics of exemplary windows will be described regarding FIGS. 3A and 3B, below.

In other embodiments, each sampled window can be processed by the schedule processor 140, and then conveyed to the client machine 150. Advantageously, the schedule processor 140, perhaps at the request of the waveform viewer 155, can convey sampled windows through the network interface 135 to the waveform viewer 155, according to transmission specifications.

In one embodiment, the OC 110 includes a parser configured to parse explicit transmission specifications sent by the waveform viewer 155, thereby, determining an order of the transmission of windows to the client machine 150, which can be different from an order of sampling windows. The OC 110 is generally configured to packetize and transmit to the waveform viewer 155 specified stored samples and associated sample offsets for each of the explicit transmission requests corresponding to at least part of a currently stored sample window. Generally, however, each sampled window is typically conveyed consecutively, although a user may select among other transference options.

Each received window of the waveform is then stored in the waveform viewer 155. Then the waveform viewer 155 receives a next window of a transmitted subset of sampled signals from the OC 110. In this way, as more and more data is transmitted to the waveform viewer 155, a more complete picture of the waveform can be generated by the waveform viewer 155, window by window. The windows may be transferred starting from the first window, such as memory 228 for display window 0, or from a middle window, such as memory 229 for display window 4. In some embodiments, the waveform viewer 155 requests a particular order of waveform windows, starting with a selected window.

In some embodiments, the OC 110 can try to predict which window will be first accessed by a user of the waveform viewer 150, and send that window, to be followed by display windows next to that window. Then, the OC 110 will send out the windows next to those two windows, and so on. In other words, a prioritization of sampled window conveyances can occur. The schedule processor 140 can act as a prioritizer circuit that prioritizes an order of transmissions of a second selected window, and also that of a third, fourth and fifth selected window from a plurality of windows, an unbounded number of windows. However, the client machine 150 can also specify which order to convey the windows by the transmit specification.

In at least some embodiments, a window conveyance over the network 145 can happen at great speed, such as 30 milliseconds to convey a one-second window. Also, in at least some embodiments of the OC 110, data conveyance through the network interface 135 advantageously occurs without down-sampling, as has occurred in conventional remote data sampling systems.

Turning now to FIG. 3A, illustrated is an example of an order of capturing and transmission of windows from the OC 110. After a trigger is generated by the sampler clock 117, multiple windows are captured by the OC 110 at regular intervals. The OC 110 determines that a second display window is the first to be conveyed to the waveform viewer 155. After this, the first window is sent. Then the third window is sent. In some embodiments, the third window is transferred to the waveform viewer immediately after the second window is transferred to the waveform viewer. This is an example of a “fixed” mode.

Turning to FIG. 3B, illustrated is an embodiment of a waveform that is sampled for conversion by an FFT. As is illustrated, a plurality of windows is captured by the OC 110. In one embodiment, the windows are then transmitted in consecutive order to the waveform viewer 155. As each window is transmitted to the waveform viewer 155, the length over which a FFT can be calculated is increased. In some embodiments, if a number of points of a plurality of windows equal a number of points used to compute an FFT, an oldest window of the plurality of windows is not employed in the FFT, instead a newest window is employed in determining the FFT. This is also an example of a “fixed” mode.

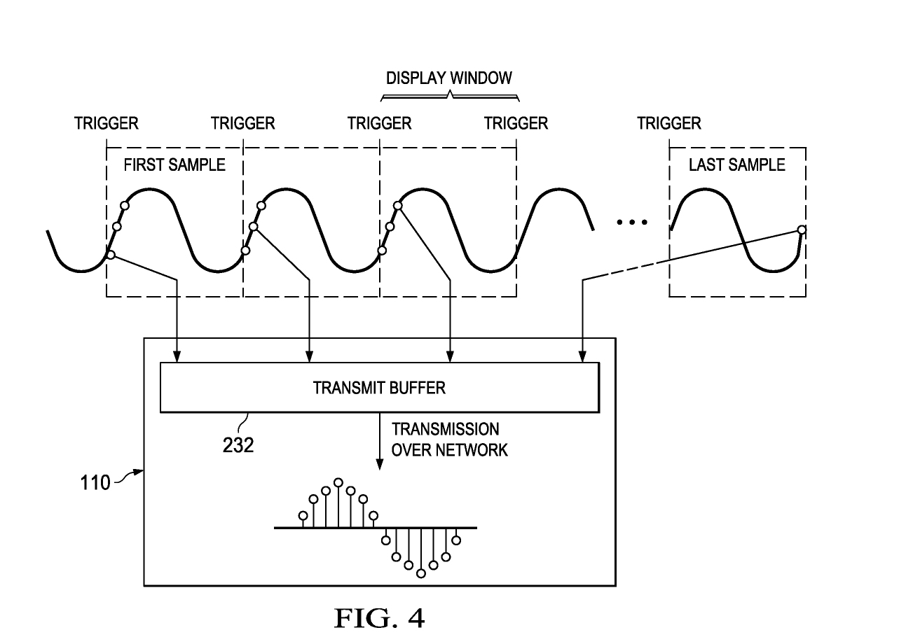

Turning back FIG. 1, described will be an alternative embodiment of an employment of the OC 100 for sampling a periodic or “pseudorandom” waveform as illustrated in conjunction with FIG. 4. Please note that the waveform viewer 155 can program the OC 110 as a real-time oscilloscope, a sampling oscilloscope, or both, as elements of the OC 110 can be realized in hardware, software, firmware, or a combination of these elements.

Generally, it is possible to capture a periodic or “pseudorandom” waveform that is faster than a sampling rate of the OC 110 by slightly and consistently altering the relative sample time within the sampled periodic or pseudorandom waveform, taking one or more samples of the waveform per period, as appropriate.

Generally, a waveform is received at the sample circuit 115. The sample circuit 115 can include, for example, an analog to digital converter and an anti-aliasing filter. The sampler clock 117 causes the sampler circuit 115 to store a single sample of a waveform into the transmit buffer 232. The sampler clock 117 provides controls for adjusting the frequency and the phase shift of the clock. All logic for actually sampling the external signal is in the sampler circuit 115. Controls of the sampler circuit 115 enable the schedule processor to dynamically instruct the sampler circuit 115 to start or stop writing samples into the local memory at a specified location.

The transmit buffer 232 includes various physical or logical locations for storage of the samples. These samples can then be processed, perhaps through employment of an FPGA, and then conveyed through the network interface 135. Also, in some embodiments, the waveform viewer 155 can perform a FFT on the periodic or pseudorandom waveform, as well as the real-time waveform.

Turning now to FIG. 4, illustrated is a conceptual example of capturing samples as may be employed by the oscilloscope core 110. As is illustrated, a trigger signal is generated by the sampler clock 117 for each of a plurality of windows, each window corresponding to a period of the waveform, by the sampler clock 117. However, a sample is captured within each window at a different point according to an increasing time delay, and stored within the memory 200, a store and transmit buffer. In so doing, a sampled picture of the waveform can be eventually displayed in a waveform viewer 155. Please note that for ease of illustration, other elements of the OC 110 are not illustrated. In some embodiments, the sampled stored data is stored in the sample storage 119 until an entire period of the waveform is sampled. This is an example of a “non-fixed” mode.

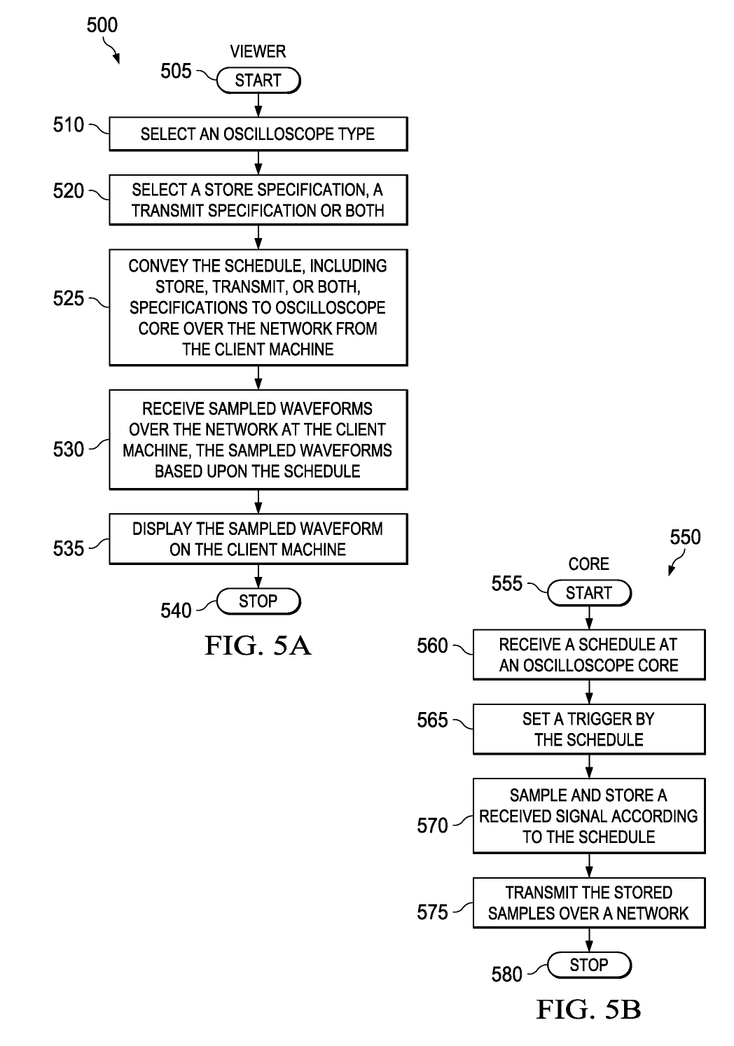

FIG. 5A is a flow diagram of one embodiment of a method 500 of displaying a waveform in real-time or otherwise captured with an OC, such as the OC 110, according to the principles of the invention. The method 500 begins in a start step 505. In a step 510, an oscilloscope type is selected—i.e., it is determined whether a captured waveform display is to be displayed as a real-time type or as a periodic type. The real-time type can be fixed or non-fixed mode. Furthermore, a spectrum analysis can be performed on captured data of a fixed or non-fixed mode.

In a step 515, a schedule for the window is selected, as are the sample window specifications. Generally, sample window specifications can include what data is to be sampled, and how it is to be sampled, for a given sample window. In one embodiment, the schedule includes one or more of: a fixed or non-fixed sampling mode; a trigger specification including: a signal name, a rising edge or falling edge, and a voltage level; a store specification; and a transmit specification.

In one embodiment, the store specification can include sample-window specifications that can overlap. In another embodiment, each schedule includes a positive or negative offset time expressed relative to an occurrence of the trigger specification and a duration of time. The method 500 uses the schedule processor 140 to control signal sampling behavior of the sampler block 112 based upon these schedules.

In a step 520, a storage specification, a transmit specification or both are selected. Generally, these specifications can include both the order and a selection of which captured data windows are to be transferred through the network interface 135.

In a step 525, the schedule, including the store specification and the transmit specification, are both conveyed over the network 145 from the client machine 150 to the OC 110. In a step 530, a sampled waveform is received over the network 145 from the OC 110 at the client machine 150. In some embodiments, this sampled waveform is received as determined by a prioritization, such as by the transmit specifications. In other embodiments, the transmit specifications are consulted in real-time. The method ends in a step stop 540.

Turning now to FIG. 5B, illustrated is a method 550 for capturing and storing waveforms in the oscilloscope core 110. After a start step 555, an oscilloscope type (real-time or periodic), a schedule is received at the OC 110 in a step 560.

In a step 565, a trigger is set per the schedule. The schedule can include such information as whether the sampling time is for a single sample, or consecutive samples (i.e., a window), the length of the window, the time between samples of the captured window, the time between windows, the number of windows and so on.

In step 570, the received signal is sampled and stored according to the schedule, which includes the oscilloscope type. In one embodiment, for each sample the oscilloscope core 110 gathers, the sample and a current value of the sample offset are written into the store buffer 226 if the sample lies within one of the store windows defined in the store specification contained in the schedule. Typically, an oldest entry is first discarded from the transmit buffer 232 if the store buffer is full. In other embodiments, the samples are stored into store buffer 226 without first checking whether they fall within a defined sample window.

In a step 575, in one embodiment, the stored samples are then transmitted over the network 145 according to the transmit specification. In another embodiment, the store samples are then transmitted over the network 145 according to an explicit request from a user. The sample and a current value of a sample offset, the time between consecutive samples, are written into the transmit buffer 232 if the sample lies within one of the transmit windows defined in the transmit specification. Again, typically, an oldest entry is first discarded from the transmit buffer if the transmit buffer 232 is full. In an alternative embodiment, the sample offset is the time since the most recent trigger event.

In one embodiment, when an end of a store window has occurred, the OC 110 determines which samples in the store buffer 226 actually lie within a store window defined by store specifications, removes from the store buffer 226 all of the samples that do not lie within the transmit window, adds the store buffer to an internal list of stored windows and allocates an empty buffer to be a new store buffer. This typically occurs after first de-allocating a sufficient quantity of an oldest window in an internal list of stored windows if insufficient memory is available.

In another embodiment, when an end of a transmit window has occurred, the OC 110: determines which of the samples in the transmit buffer lie within the transmit window, removes from the transmit buffer all those samples that do not lie within the transmit window, packetizes and transmits to the viewer samples and associated sample offsets remaining in the transmit buffer and clears the transmit buffer. The method ends in a step 580.

In one embodiment of the method 550, a sample offset is set. The method 550 begins gathering the samples at each transition of a sampling clock. In another embodiment, the method 500 begins searching for an occurrence of the trigger event specified in the schedule. The core 110 can be configured to change the sample offset to a value less than a period of a sampling clock and to gather succeeding samples at a new value offset from each transition of the sampling clock. This can occur in step 570.

In another embodiment of the method 550, for each sample the core 110 gathers, the core 110 is further configured to: (a) write the sample and a current value of the sample offset into a store buffer if the sample lies within one of the store windows defined in the store specification contained in the schedule; (b) first discard an oldest entry from a store buffer if the store buffer is full before carrying out the step (a); (c) write the sample and the current value of the sample offset into a transmit buffer if the sample lies within one of the transmit windows defined in the transmit specification; and (d) first discard an oldest entry from the transmit buffer if the transmit buffer is full before carrying out the step (c) This can occur in step 570.

In a further embodiment of the method 550, if the core 110 detects that an end of a store window has occurred, the core 110 is further configured to: (a) determine which samples in a store buffer actually lie within the store window; (b) remove from the store buffer all of the samples that do not lie within the store window; (c) add the store buffer to an internal list of stored windows; (d) allocate an empty buffer to be a new store buffer; and (e) first de-allocate a sufficient quantity of an oldest windows in an internal list of stored windows if insufficient memory is available to carry out the step (d). This can also occur in step 570.

In a yet further embodiment of the method 550, if the core 110 detects that an end of a transmit window has occurred, the core 110 is further configured to: determine which of the samples in the transmit buffer lie within the transmit window; remove from the transmit buffer all those samples that do not lie within the transmit window, packetize and transmit to the viewer samples and associated sample offsets remaining in the transmit buffer and clear the transmit buffer. This can also occur in step 570.

Those skilled in the art to which the invention relates will appreciate that other and further additions, deletions, substitutions and modifications may be made to the described embodiments without departing from the scope of the invention.

What is claimed is:

1. A system, comprising:
(a) a core having a local memory and configured to:
gather samples of an external signal at a specified sampling rate; and
write samples into said local memory based on a schedule and transmit said samples over a network; and
(b) a viewer couplable to said core over said network and configured to:
receive said samples over said network; and
display a waveform based on said samples.

2. The system as recited in claim 1 wherein said core is further configured to determine, in real-time, said samples based on said schedule received from said viewer.

3. The system as recited in claim 2 wherein said core is further configured to determine which samples to transmit by one of:
consulting said schedule in real-time, and
responding to an explicit transmission request from said viewer.

4. The system as recited in claim 3 wherein said schedule comprises at least one of:
a fixed or non-fixed sampling mode;
a trigger specification including:
a signal name,
a rising edge or falling edge, and
a voltage level;
a store specification; and
a transmit specification.

5. The system as recited in claim 4 wherein said transmit specification and said store specification each comprises some number of sample windows, each of those comprising:
a positive or negative offset time expressed relative to an occurrence of said trigger specification, and
a duration of time.

6. The system as recited in claim 5 wherein, following receipt of said schedule, said core is further configured to:
set a sample offset to zero;
begin gathering said samples at each transition of a sampling clock; and
begin a search for an occurrence of said trigger specified in said schedule;
and when (a) said schedule specifies said sampling mode to be a non-fixed sampling mode, and
(b) said trigger occurs,
said core is configured to:
(i) change said sample offset to a value less than a period of said sampling clock; and
(ii) gather succeeding samples at said new value offset from each transition of said sampling clock.

7. The system as recited in claim 6 wherein, for each sample said core gathers, said core is further configured to:
(a) write said sample and said current value of said sample offset into a store buffer if said sample lies within one of said store windows defined in said store specification contained in said schedule;
(b) first discard an oldest entry from said store buffer if said store buffer is full before carrying out said step (a);
(c) write said sample and the current value of said sample offset into a transmit buffer if said sample lies within one of said transmit windows defined in said transmit specification; and
(d) first discard an oldest entry from said transmit buffer if said transmit buffer is full before carrying out said step (c).

8. The system as recited in claim 7 wherein when if core detects that an end of a store window has occurred, said core is further configured to:
(a) determine which samples in said store buffer actually lie within said store window;
(b) remove from said store buffer all of said samples that do not lie within said store window;
(c) add said store buffer to an internal list of stored windows;
(d) allocate an empty buffer to be a new store buffer; and
(e) first deallocate a sufficient quantity of an oldest windows in an internal list of stored windows if insufficient memory is available to carry out the step (d).

9. The system as recited in claim 7 wherein if said core detects that an end of a transmit window has occurred, said core is further configured to:
determine which of the samples in said transmit buffer lie within said transmit window;
remove from said transmit buffer all those samples that do not lie within said transmit window;
packetize and transmit to said viewer samples and associated sample offsets remaining in said transmit buffer; and
clear said transmit buffer.

10. The system as recited in claim 1 wherein said viewer is configured to specify said sampling mode to be a fixed sampling mode and display received samples in a waveform.

11. The system as recited in claim 1 wherein said viewer is configured to specify said sampling mode to be a non-fixed sampling mode and display received samples in a waveform such that said viewer emulates a sampling oscilloscope.

12. The system as recited in claim 1 wherein said viewer is configured to specify said sampling mode to be a fixed sampling mode, and perform a spectral analysis on received samples and display a resulting spectral decomposition such that said viewer emulates a spectrum analyzer.

13. The system as recited in claim 1 wherein said core and said viewer are accessible through a published application programming interface (API).

14. The system as recited in claim 1 wherein said core and said viewer communicate using a published protocol over said network.

15. The system as recited in claim 1 wherein said core is further configured to present multiple logically independent virtual cores thereby to permit multiple viewers independently to gain access to and control said logically independent virtual cores.

16. A method, comprising:
receiving a schedule at an oscilloscope core;
storing samples of a received signal according to said schedule; and
transmitting, over a network, said stored samples.

17. The method as recited in claim 16 further comprising determining which of said samples to transmit by one of:
consulting a transmit specification of a schedule, and
responding to an explicit transmission request from said viewer.

18. The method as recited in claim 17 wherein said schedule comprises:
a fixed or non-fixed sampling mode; and
a trigger specification including at least one of:
a signal name,
a rising edge or falling edge, and
a voltage level;
a transmit specification; and
a store specification.

19. The method as recited in claim 18 wherein said transmit specification and said store specification each comprises some number of sample windows, each of those comprising:
a positive or negative offset time expressed relative to an occurrence of said trigger specification, and
a duration of time.

20. The method as recited in claim 19 further comprising determining:
setting a sample offset to zero;
gathering said samples at each transition of a sampling clock;
searching for an occurrence of said trigger specified in said schedule;
when said trigger occurs and said schedule specifies said sampling mode to be a non-fixed sampling mode:
(a) changing said sample offset to a value less than a period of said sampling clock; and
(b) gathering succeeding samples at said new value offset from each transition of said sampling clock.

21. The method as recited in claim 20 further comprising, when an end of a transmit window has occurred:
determining which of the samples in said transmit buffer lie within said transmit window;
removing from said transmit buffer all those samples that do not lie within said transmit window;
packetizing and transmit to said viewer samples and associated sample offsets remaining in said transmit buffer; and
clearing said transmit buffer.

22. The method as recited in claim 16 further comprising packetizing and transmitting specified stored samples and associated sample offsets for each of said explicit transmission requests corresponding to at least part of a currently stored sample window.

23. The method as recited in claim 16 further comprising communicating with said oscilloscope core using a published protocol over said network.

24. A method of using a viewer of a client machine, comprising:
selecting an oscilloscope type;
selecting a store specification, or a transmit specification, or both;
conveying a schedule including said store specification, or said transmit specification, or both to an oscilloscope core over a network;
receiving sampled waveforms over said network from an oscilloscope core based upon said schedule; and
displaying said sampled waveforms on said viewer of said client machine.

25. The method of claim 24, wherein said schedule comprises:
a fixed or non-fixed sampling mode;
a trigger specification including at least one of:
a signal name,
a rising edge or falling edge, and
a voltage level;
a store specification; and
a transmit specification.

26. The method as recited in claim 25 further comprising determining:
setting a sample offset to zero;
gathering said samples at each transition of a sampling clock; and
searching for an occurrence of said trigger specified in said schedule when said schedule specifies said sampling mode to be a fixed sampling type.
